(19) United States
(12) Patent Application Publication
(10) Pub. No.: US 2026/0239945 A1
(43) Pub. Date: Aug. 13, 2026

(54) Trench Tip Squaring in Self-Aligned Multi-Patterning Process

(71) Applicant: Applied Materials, Inc., Santa Clara, CA (US)

(72) Inventors: Sivanandha Krishnan Kanakasabapathy, Pleasanton, CA (US); San-Kuei Lin, Los Gatos, CA (US); Steven Sherman, Newton, MA (US); Abhijit Basu Mallick, Sunnyvale, CA (US)

(73) Assignee: Applied Materials, Inc., Santa Clara, CA (US)

(21) Appl. No.: 19/050,705

(22) Filed: Feb. 11, 2025

(51) Int. Cl. H10W 20/00; H01J 37/32; H10P 14/60; H10P 50/28

(52) U.S. Cl. CPC H10W 20/069; H01J 37/32009; H10P 14/6336; H10P 14/6339; H10P 50/283; H10W 20/032; H10W 20/056; H01J 2237/3341

(57) ABSTRACT

The Disclosure is directed to trench tip squaring in self-aligned multi-patterning process. One method may include forming a plurality of linear spacers over a base layer of a semiconductor device, wherein a set of adjacent linear spacers of the plurality of linear spacers define a trench. The method may further include providing a pillar in the trench, wherein the pillar comprises a plurality of recessed corner areas at an intersection between the pillar and the set of adjacent linear spacers. The method may further include performing a plasma treatment to form a film layer in the plurality of recessed corner areas, wherein the plasma treatment comprises directing ions to the plurality of linear spacers at a non-perpendicular angle relative to a plane defined by an upper surface of the base layer.

### FIELD OF THE DISCLOSURE

The present embodiments relate to semiconductor device patterning and, more particularly, to trench tip squaring in a self-aligned multi-patterning process.

### BACKGROUND OF THE DISCLOSURE

Self-aligned multi-patterning (SAMP) techniques are used to form components of semiconductor devices, such as fin-type field effect transistor (FinFET) devices and the like. The need for constantly reduced dimensions is one of the driving forces in the development of integrated circuit processing. By reducing the size dimensions, cost-benefit and device performance improvements can be obtained. This scalability creates inevitable complexity in process flow, especially on patterning techniques. As smaller transistors are manufactured, the critical dimension (CD) or resolution of patterned features is becoming more challenging to produce, particularly in high volume.

A conventional SAMP flow has several steps, including mandrel (or core) formation, spacer deposition, spacer etch, and mandrel pull. In some devices, pillars are also formed between adjacent spacers. However, as the pitch scales, forming a uniform, e.g., square, intersection between each pillar and the spacers becomes more challenging. Instead, the pillars have a cylindrical shape, which leads to spikes, or a “devil’s horn,” formed as patterning continues to lower levels of the device. In turn, these features may become a metallization failure point or a high electric field TDDB (Time Dependence on Dielectric Breakdown) failure point.

It is with respect to these and other deficiencies that the present disclosure is provided.

### SUMMARY

This Summary is provided to introduce a selection of concepts in a simplified form that are further described below in the Detailed Description. This Summary is not intended to identify key features or essential features of the claimed subject matter, nor is it intended as an aid in determining the scope of the claimed subject matter.

In one aspect, a method may include forming a plurality of linear spacers over a base layer of a semiconductor device, wherein a set of adjacent linear spacers of the plurality of linear spacers define a trench. The method may further include providing a pillar in the trench, wherein the pillar comprises a plurality of recessed corner areas at an intersection between the pillar and the set of adjacent linear spacers. The method may further include performing a plasma treatment to form a film layer in the plurality of recessed corner areas, wherein the plasma treatment comprises directing ions to the plurality of linear spacers at a non-perpendicular angle relative to a plane defined by an upper surface of the base layer.

In another aspect, a self-aligned patterning method may include forming a plurality of linear spacers over a base layer of a semiconductor device, wherein a set of adjacent linear spacers of the plurality of linear spacers define a trench, wherein a pillar is formed in the trench, and wherein the pillar comprises a plurality of recessed corner areas at an intersection between the pillar and the set of adjacent linear spacers. The method may further include performing a plasma treatment to form a film layer in the plurality of recessed corner areas and along a sidewall of the pillar, wherein the plasma treatment comprises directing ions to the plurality of linear spacers at a non-perpendicular angle relative to a plane defined by an upper surface of the base layer.

In yet another aspect, a plasma processing tool may include a plasma chamber for generating plasma, wherein ions are extracted from the plasma and directed to a semiconductor device, and a main controller operatively coupled to plasma chamber. The main controller is adapted to perform a plasma treatment by directing the ions to a plurality of linear spacers of the semiconductor device to form a film layer in a plurality of recessed corner areas and along a sidewall of a pillar, wherein the pillar is formed between a set of adjacent linear spacers of the plurality of linear spacers, and wherein the ions are directed to the plurality of linear spacers at a non-perpendicular angle relative to a plane defined by an upper surface of the base layer of the semiconductor device.

### BRIEF DESCRIPTION OF THE DRAWINGS

The accompanying drawings illustrate exemplary approaches of the disclosure, including the practical application of the principles thereof, as follows:

FIG. 1A is a top view of a device structure including a plurality of trenches and a plurality of patterning features, according to embodiments of the present disclosure;

FIG. 1B is a side cross-sectional view, along cutline Y-Y’ of FIG. 1A, illustrating the device structure, according to embodiments of the present disclosure;

FIG. 1C is a perspective view of a portion of the device structure of FIG. 1A, according to embodiments of the present disclosure;

FIG. 1D is a top view of a pillar of the device structure of FIG. 1A, according to embodiments of the present disclosure;

FIG. 2A is a top view of the device structure following partial removal of a spacer layer from the plurality of patterning features, according to embodiments of the present disclosure;

FIG. 2B is a side cross-sectional view, along cutline Y-Y’ of FIG. 2A, illustrating the device structure, according to embodiments of the present disclosure;

FIG. 2C is a perspective view of a portion of the device structure of FIG. 2A, according to embodiments of the present disclosure;

FIG. 3A is a top view of the device structure following formation of a film layer, according to embodiments of the present disclosure;

FIG. 3B is a side cross-sectional view, along cutline Y-Y’ of FIG. 3A, illustrating the device structure, according to embodiments of the present disclosure;

FIG. 3C is a perspective view of a portion of the device structure of FIG. 3A, according to embodiments of the present disclosure;

FIG. 4A is a top view of the device structure following a plasma treatment, according to embodiments of the present disclosure;

FIG. 4B is a side cross-sectional view, along cutline Y-Y’ of FIG. 4A, illustrating the device structure, according to embodiments of the present disclosure;

FIG. 4C is a perspective view of a portion of the device structure of FIG. 4A, according to embodiments of the present disclosure;

FIG. 4D is a top view of a pillar of the device structure of FIG. 4A, according to embodiments of the present disclosure;

FIG. 5A is a top view of the device structure following a transfer etch process, according to embodiments of the present disclosure;

FIG. 5B is a side cross-sectional view, along cutline Y-Y’ of FIG. 5A, illustrating the device structure, according to embodiments of the present disclosure;

FIG. 5C is a perspective view of a portion of the device structure of FIG. 5A, according to embodiments of the present disclosure;

FIG. 6 illustrates a schematic diagram of a processing apparatus according to embodiments of the present disclosure;

FIG. 7A illustrates an exemplary processing apparatus according to embodiments of the disclosure;

FIG. 7B depicts details of an exemplary extraction plate according to embodiments of the disclosure; and

FIG. 8 is a flow diagram illustrating an approach for trench tip squaring in a self-aligned multi-patterning process according to embodiments of the present disclosure.

The drawings are not necessarily to scale. The drawings are merely representations, not intended to portray specific parameters of the disclosure. The drawings are intended to depict exemplary embodiments of the disclosure, and therefore are not to be considered as limiting in scope. In the drawings, like numbering represents like elements.

Furthermore, certain elements in some of the figures may be omitted, or illustrated not-to-scale, for illustrative clarity. The cross-sectional views may be in the form of "slices", or "near-sighted" cross-sectional views, omitting certain background lines otherwise visible in a "true" cross-sectional view, for illustrative clarity. Furthermore, for clarity, some reference numbers may be omitted in certain drawings.

### DETAILED DESCRIPTION

Methods and devices in accordance with the present disclosure will now be described more fully hereinafter with reference to the accompanying drawings, where various embodiments are shown. The methods and devices may be embodied in many different forms and are not to be construed as being limited to the embodiments set forth herein. Instead, these embodiments are provided so the disclosure will be thorough and complete, and will fully convey the scope of the methods to those skilled in the art.

Embodiments described herein provide an integrated solution that optimizes film deposition and plasma etching along a pillar formed within a back-of-the-line (BEOL) non-mandrel trench defined by adjacent linear spacers. Squaring of the non-mandrel trench in an area adjacent the pillar reduces the chance of electrical fail points, thereby increasing yield and reliability.

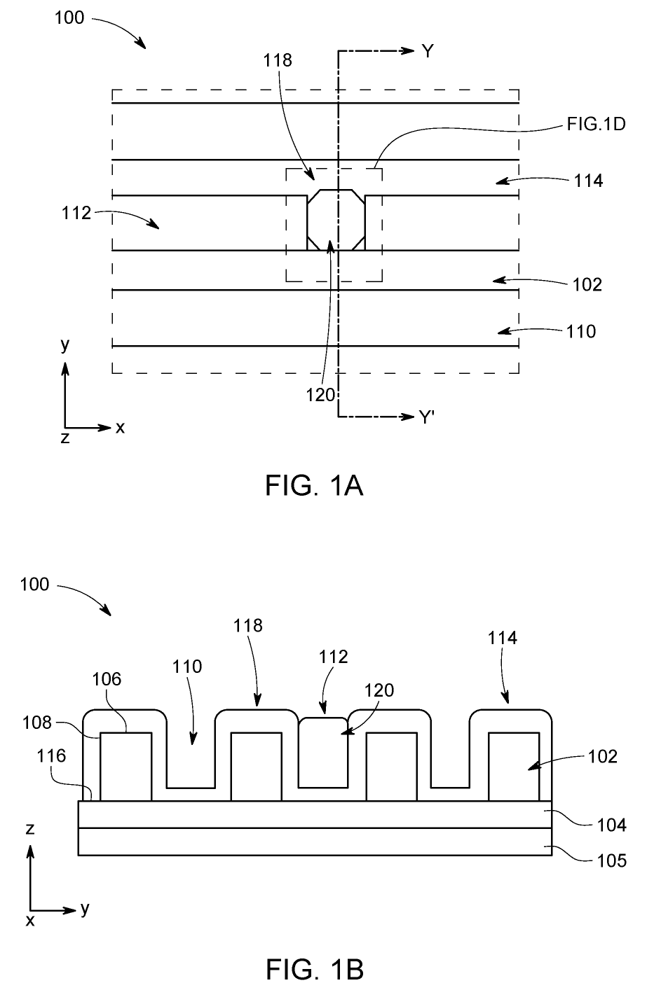

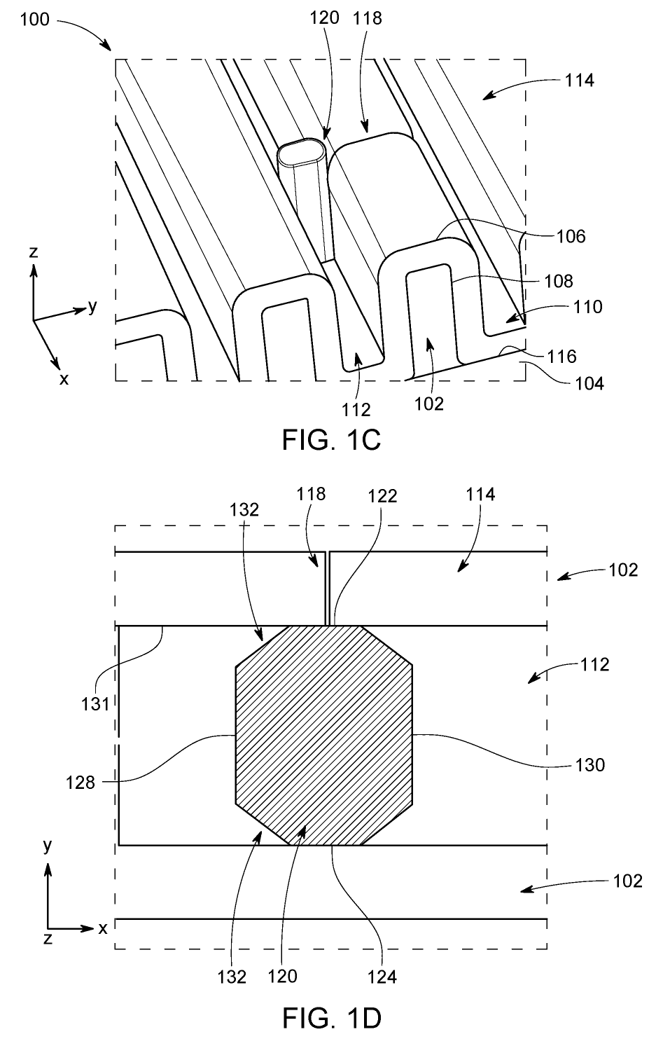

FIG. 1A is a simplified top view, FIG. 1B is a cross-sectional view along cutline Y-Y’ of FIG. 1A, and FIG. 1C is a perspective view, of a portion of a semiconductor device (hereinafter “device”) 100 according to one or more embodiments of the disclosure. The device 100 may include a plurality of linear patterning features (e.g., mandrel pattern) 102 atop a first base layer 104, which may be a dielectric. The first base layer 104 may be further atop one or more second base layers 105, such as a substrate.

Each linear patterning feature 102 includes an upper surface 106 and a set of sidewall surfaces 108 connected to the upper surface 106. The linear patterning features 102 may define a first plurality of trenches 110 adjacent a second plurality of trenches 112 (i.e., non-mandrel trenches), wherein each of the first plurality of trenches 110 and the second plurality of trenches 112 may be partially defined by an upper surface 116 of the first base layer 104.

As further shown, a spacer layer 114 may be formed over the linear patterning features 102 and atop the upper surface 116 of the first base layer 104. The spacer layer 114 may be a thin film conformally formed over the device, wherein the thin film is made from an oxide, a nitride, silicon, or any combination thereof, e.g., silicon nitride, silicon oxide, or silicon oxynitride. Two adjacent trenches of the first plurality of trenches 110 may be separated from one another by a tip-to-tip portion 118 of the spacer layer 114.

The device 100 may also include one or more pillars 120 formed in the second trench 112. Although non-limiting, the pillar 120 may be dielectric material, which is deposited or otherwise formed atop the spacer layer 114. As best shown in FIG. 1D, the pillar 120 may include a first end 122 opposite a second end 124, and a first side 128 opposite a second side 130. The first and second ends 122, 124 may be in contact with the spacer layer 114 of two adjacent patterning features 102. In some embodiments, the first end 122 may be in contact with, or abut, the tip-to-tip portion 118 of the spacer layer 114. The first and second sides 128, 130 are exposed within the second trench 112, and may extend perpendicular, or substantially perpendicular, to a plane defined by a sidewall 131 of the spacer layer 114. In other embodiments, the first and/or second sides 128, 130 may have a curved profile.

The pillar 120 may further define one or more recessed corner areas 132 where the pillar 120 connects with the spacer layer 114. Said differently, the recessed corner areas 132 may be sloped or curved crevasses resulting from incomplete formation between the first and second ends 122, 124 and the spacer layer 114. If the recessed corner areas 132 are permitted to remain, this pattern will be transferred to one or more underlayers (e.g., the first base layer 104) of the device 100, potentially leading to points of failure. To mitigate this issue, the recessed corner areas 132 can be filled, as will be described in greater detail below.

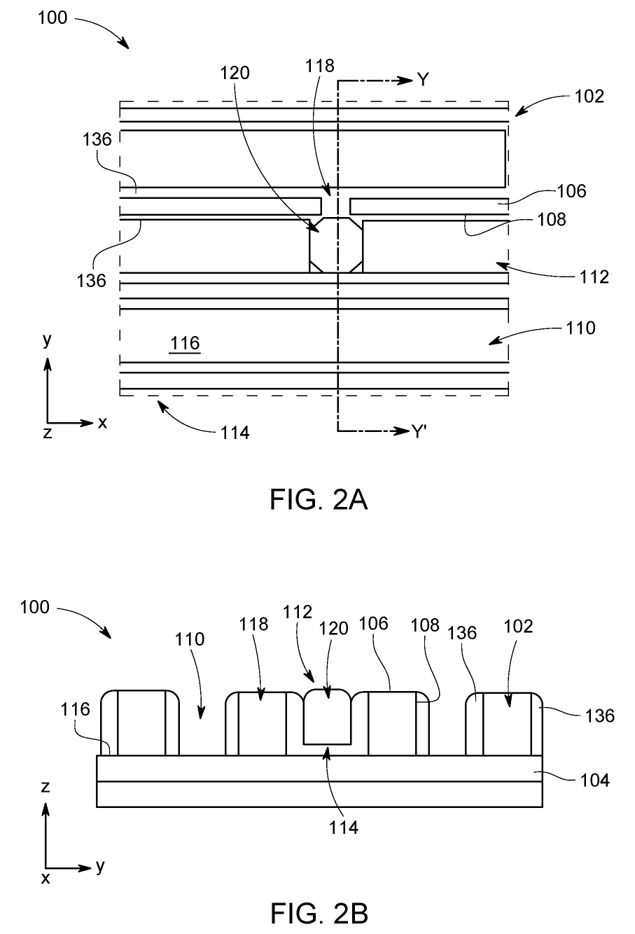

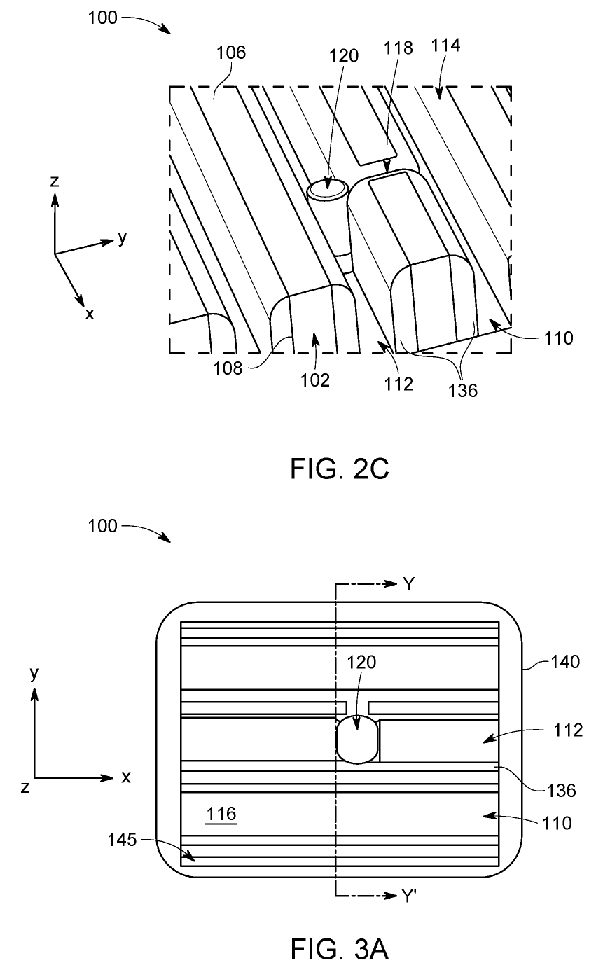

As shown in FIGS. 2A – 2C, the spacer layer 114 may then be etched to leave behind multiple sets of adjacent linear spacers 136 (sometimes referred to as sidewall spacers) on the sidewall surfaces 108 of the patterning features 102. For example, a reactive ion etch (RIE) process may be performed to remove the spacer layer 114 from the upper surfaces 106 of each of the patterning features 102 and from the upper surface of 116 of the first base layer 104 in the first and second trenches 110, 112. The pillar 120 is generally unaffected by the RIE process.

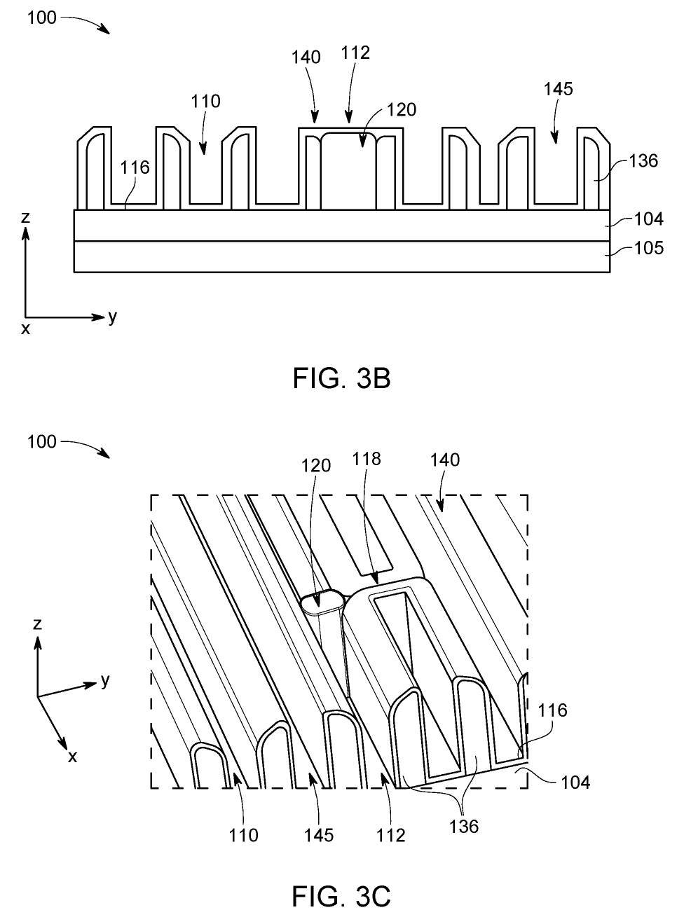

As shown in FIGS. 3A – 3C, a film layer 140 may then be formed over the device 100, including over each of the linear spacers 136, the pillar 120, and the first base layer 104 within each of the first trenches 110 and the second trenches 112. In some embodiments, the film layer 140 is a thin film (e.g., carbon), which may be a conformal low-temperature molecular layer deposited (MLD) coating over the entire device 100. In other embodiments, the film layer 140 may be formed via atomic layer deposition (ALD). Prior to deposition of the film layer 140, the linear patterning features 102 may be removed (e.g., etched) to form a plurality of mandrel trenches 145.

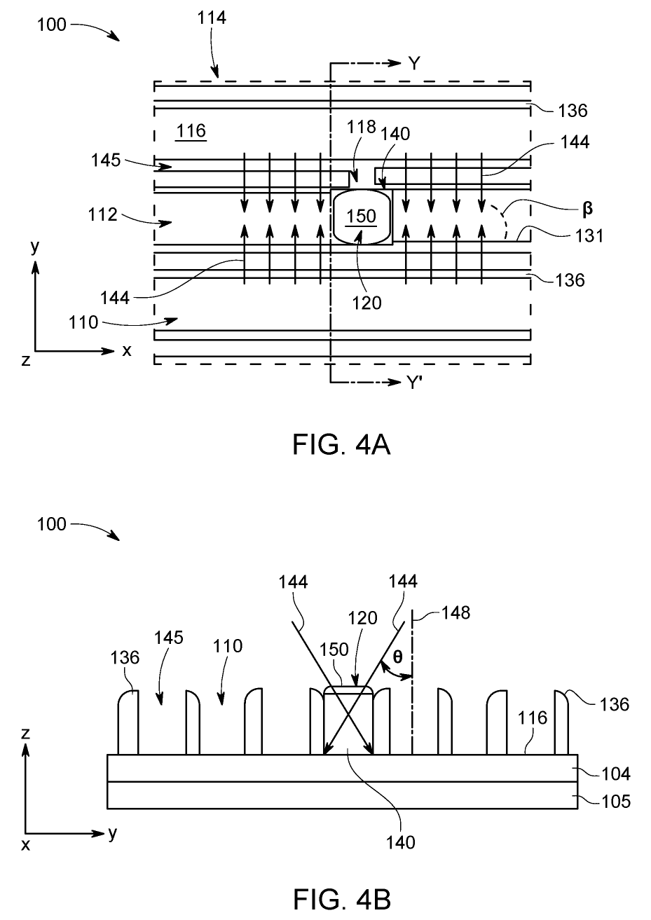

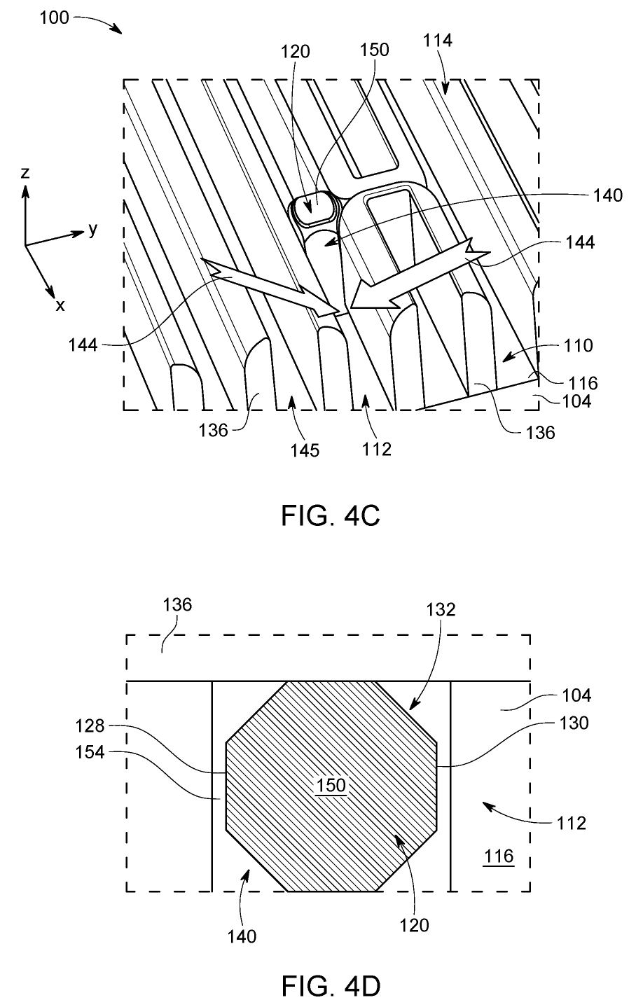

As shown in FIGS. 4A – 4D, a plasma treatment may then be performed to remove a portion of the film layer 140 from the device 100. In some embodiments, the plasma treatment may include directing ions 144 into the first and second trenches 110, 112 at a first non-zero angle (θ) (FIG. 4B) relative to a perpendicular 148 extending from the upper surface 116 of the first base layer 104 as part of a plasma etch process. Said another way, the ions 144 may be directed into the first and second trenches 110, 112 at a non-perpendicular angle relative to a plane defined by the upper surface 116 of the base layer 104. Although non-limiting, the first non-zero angle θ may be between 10-80 degrees, 20-70 degrees, 30-60 degrees, etc., and may depend upon the dimensions of the first and second trenches 110, 112.

The ions 144 may also be directed to the device 100 at a second angle (β) (FIG. 4A), i.e., perpendicular to the plane defined by the sidewall 131 of the spacer layer 114. As a result, the ions 144 may generally impact all exposed surfaces of the linear spacers 136, as well as the upper surface 116 of the first base layer 104, to remove the film layer 140 therefrom. However, the film layer 140 may remain along portions of the pillar 120. For example, as better shown in FIG. 4D, the film layer 140 may be etched from an upper surface 150 of the pillar 120 but remain along the first and second sides 128, 130 and within the recessed corner areas 132. The film layer 140 fills the recessed corner areas 132 to square the ends of the second trench 112 at the intersection between the pillar 120 and the linear spacers 136. A thin section 154 of the film layer 140 may also remain over the first and second sides 128, 130 of the pillar 120. This squaring of the ends of the second trench 112 enables more accurate pattern transfer in subsequent steps. In various embodiments, the ions 144 may include a selective oxygen or hydrogen chemistry.

In other embodiments, the film layer 140 may be formed within the recessed corner areas 132 without first being formed over the entire device 100. For example, the plasma treatment may include depositing the film layer 140 and simultaneously etching the film layer 140 so that substantially no material accumulates over the linear spacers 136 or the upper surface 116 of the first base layer 104. Instead, due to the angle(s) of the ions 144 being directed to the device 100, the film layer 140 is formed primarily within the recessed corner areas 132. In some embodiments, the film layer 140 may be formed using a high-density-plasma process, such as a plasma chemical vapor deposition (CVD) process, wherein the material deposition-to-sputter ratio is optimized to prevent buildup of material on the linear spacers 136 and the first base layer 104. Because the etchant is less able to reach the recessed corner areas 132 due to the angle(s) of the ions 144, material will form within the recessed corner areas 132 until filled.

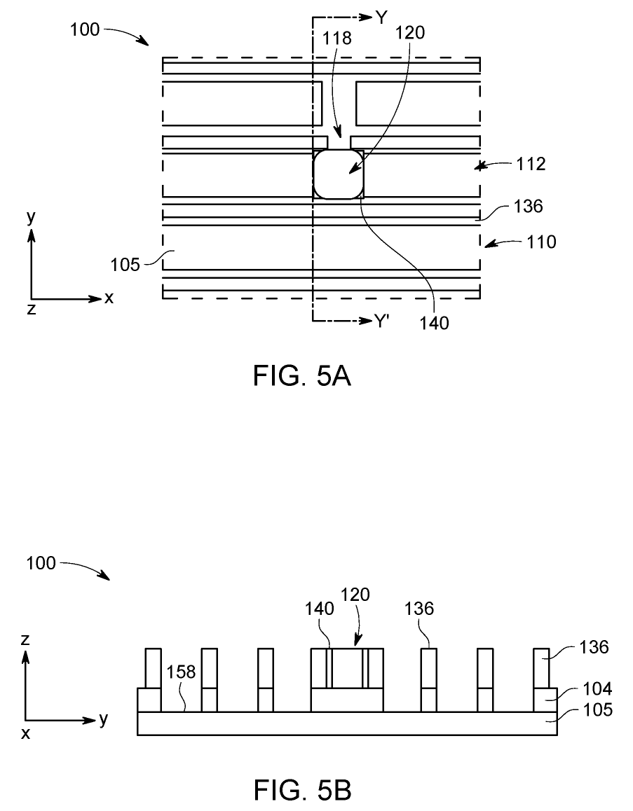

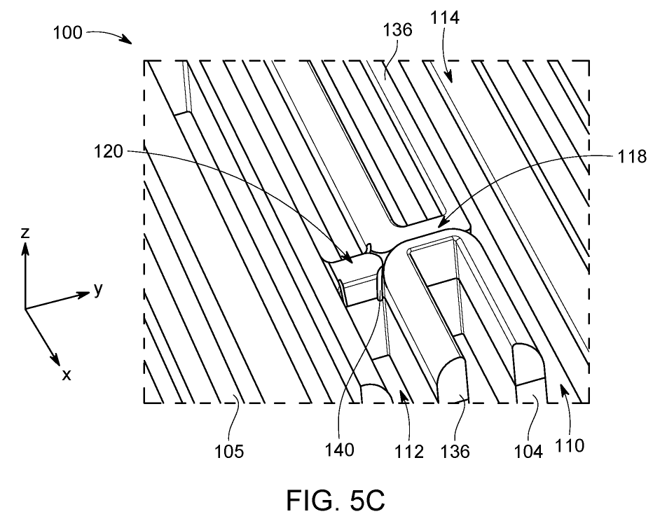

As shown in FIGS. 5A – 5D, a transfer etch process may be performed whereby the first base layer 104 is removed selective to an upper surface 158 of the second base layer 105. A portion of the linear spacers 136 may remain atop the first base layer 104, as shown, or the linear spacers 136 may alternatively be removed leaving the first base layer 104 as a new feature pattern.

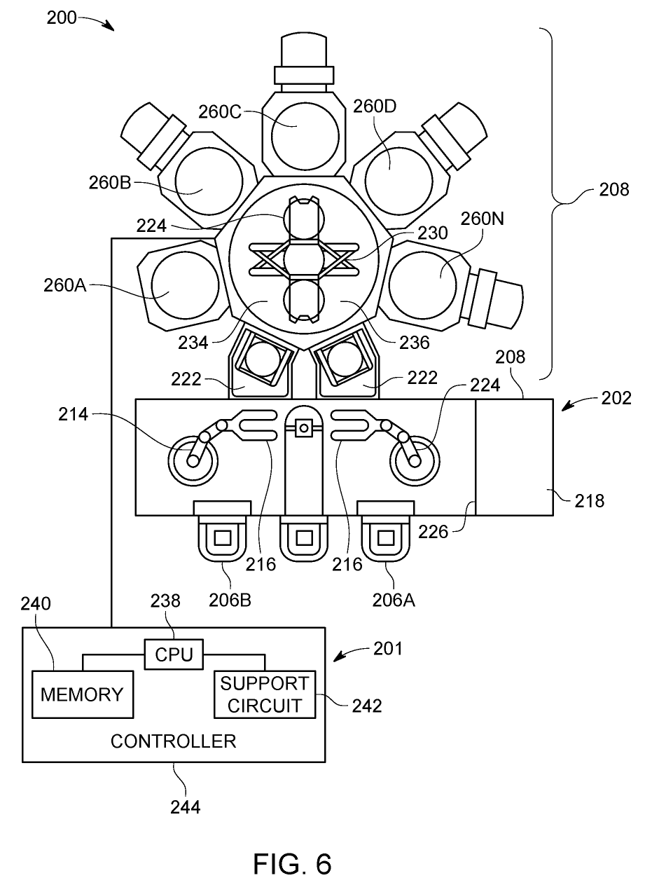

FIG. 6 is a schematic top plan view of an exemplary cluster processing system 200 that includes one or more of the processing chambers operable to form the device 100 described herein. In one embodiment, the cluster processing system 200 may be an integrated processing system commercially available from Applied Materials, Inc., located in Santa Clara, CA. It is contemplated that other processing systems (including those from other manufacturers) may be adapted to benefit from the disclosure.

The cluster processing system 200 may include a vacuum-tight processing platform 204, a factory interface 202, and a system controller 244. The platform 204 includes a plurality of processing chambers 260A – 260N and at least one load-lock chamber 222 that is coupled to a vacuum substrate transfer chamber 236. The factory interface 202 is coupled to the transfer chamber 236 by the load lock chambers 222.

In one embodiment, the factory interface 202 comprises at least one docking station 208 and at least one factory interface robot 214 to facilitate transfer of substrates. The docking station 208 is configured to accept one or more front opening unified pod (FOUP). The factory interface robot 214 having a blade 216 disposed on one end of the robot 214 is configured to transfer the substrate from the factory interface 202 to the processing platform 204 for processing through the load lock chambers 222. Optionally, one or more metrology stations 218 may be connected to a terminal 226 of the factory interface 202 to facilitate measurement of the substrate from the FOUPS 206A-B.

Each of the load lock chambers 222 may have a first port coupled to the factory interface 202 and a second port coupled to the transfer chamber 236. The load lock chambers 222 are coupled to a pressure control system (not shown) which pumps down and vents the load lock chambers 222 to facilitate passing the substrate between the vacuum environment of the transfer chamber 236 and the substantially ambient (e.g., atmospheric) environment of the factory interface 202.

In one embodiment of the cluster processing system 200, the cluster processing system 200 may include one or more processing chambers 260A – 260N, which may include a deposition chamber (e.g., physical vapor deposition chamber, chemical vapor deposition, or other deposition chambers), annealing chamber (e.g., high pressure annealing chamber, RTP chamber, laser anneal chamber), etch chamber, cleaning chamber, curing chamber, lithographic exposure chamber, or other similar type of semiconductor processing chambers. More specifically, etch chamber 260A may include a tool operable to perform an angled plasma treatment using ions delivered at a non-zero angle to form the film layer 140 within the recessed corner areas 132, as described herein with respect to device 100. Meanwhile, deposition chamber 260B may include a deposition tool operable to perform an angled material/film deposition using a reactive plasma beam delivered vertically or at a non-zero angle to form the film layer 140, as described herein with respect to devices 100. In other embodiments, the etch and deposition processes can be performed in the same chamber, such as an angled plasma beam chamber, e.g., by changing the chemistry being used in the chamber. The etch and deposition processes may occur sequentially, but they may also occur simultaneously, by running both the etch and the deposition chemistries at the same time.

The transfer chamber 236 has a vacuum robot 230 disposed therein. The vacuum robot 230 has a blade 234 capable of transferring substrates 224 among the load lock chambers 222, the metrology system 210 and the processing chambers 260A – 260N.

The system controller 244 is coupled to the cluster processing system 200. The system controller 244, which may include the computing device 201 or be included within the computing device 201, controls the operation of the cluster processing system 200 using a direct control of the processing chambers 260A – 260N of the cluster processing system 200. Alternatively, the system controller 244 may control the computers (or controllers) associated with the processing chambers 260A – 260N and the cluster processing system 200. In operation, the system controller 244 also enables data collection and feedback from the respective chambers to optimize performance of the cluster processing system 200.

The system controller 244, much like the computing device 201 described above, generally includes a central processing unit (CPU) 238, a memory 240, and support circuits 242. The CPU 238 may be one of any form of a general-purpose computer processor that can be used in an industrial setting. The support circuits 242 are conventionally coupled to the CPU 238 and may comprise cache, clock circuits, input/output subsystems, power supplies, and the like. The software routines transform the CPU 238 into a specific purpose computer (controller) 244. The software routines may also be stored and/or executed by a second controller (not shown) that is located remotely from the cluster processing system 200.

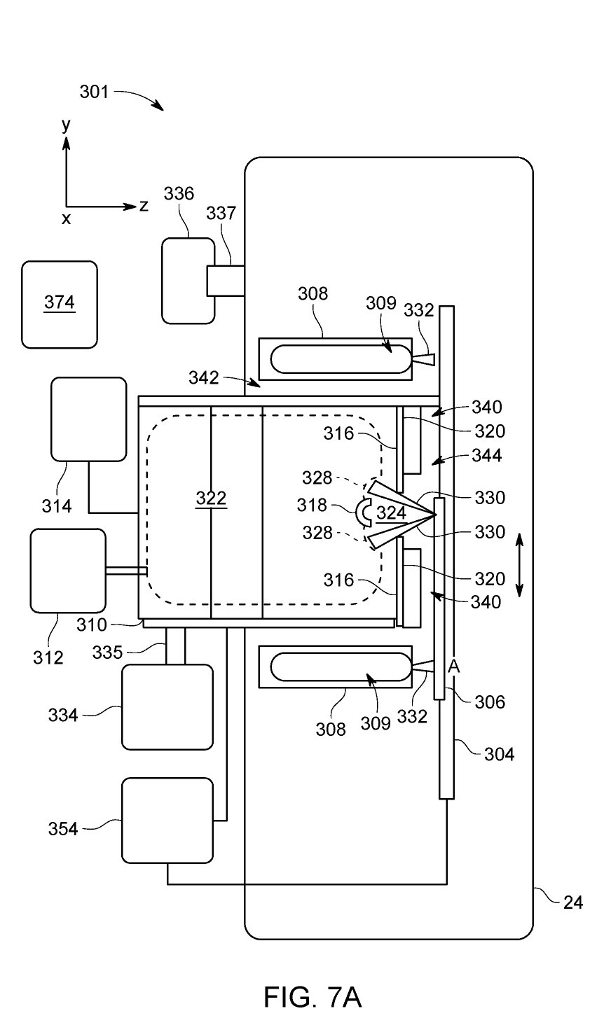

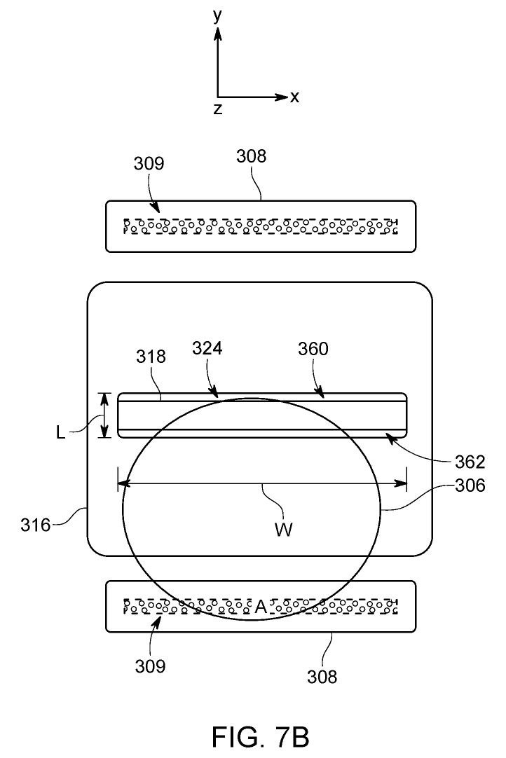

FIGS. 7A – 7B are schematic cross-sectional views of a processing apparatus 301 including an exemplary plasma processing chamber 300 suitable for performing a patterning process. One example of the plasma processing chamber 300 is a patterning chamber available from Applied Materials, Inc., located in Santa Clara, CA. The plasma processing chamber 300 may correspond to one of the processing chambers 260A – 260N of the cluster processing system 200 described above. It is contemplated that other process chambers, including those from other manufactures, may be adapted to practice embodiments of the disclosure. It will be further contemplated that the components of the processing apparatus 301 are not necessarily to scale. The drawings are merely representations, not intended to portray specific parameters of the disclosure.

The apparatus 301 may include various components that operate together as an apparatus providing novel and improved etching of a substrate 306. As illustrated, the apparatus 301 may include a process chamber 302 and a substrate stage 304 disposed within the process chamber 302. The substrate stage 304 may be movable at least along a direction parallel to the Y-axis in the Cartesian coordinate system shown and a 360-degree rotational motion along the Z-axis.

The apparatus 301 further includes at least one reactive gas source, shown as the reactive gas source 308. The reactive gas source 308 may have a reactive gas outlet 309 disposed within the process chamber 302. The reactive gas source 308 may be employed to deliver reactive gas 332 to the substrate 306 when the substrate 306 is adjacent the reactive gas source 308. In various embodiments, the reactive gas 332 may be capable of reacting with material of the substrate 306, wherein a first product layer comprising the reactive gas 332 and material from the substrate 306 is formed on an outer surface of the substrate. For example, in one particular non-limiting embodiment, the reactive gas 332 may comprise chlorine or a chlorine-containing material, while the substrate 306 is silicon. The reactive gas 332 may be delivered as a neutral species, may be delivered as a radical, may be delivered as an ion or may be delivered as a combination of neutrals, radicals and ions in some embodiments. A product layer may form as layer composed of a monolayer of chlorine species bonded to an underlayer of silicon species. The embodiments are not limited in this context.

The apparatus 301 further includes a plasma chamber 310. The plasma chamber 310 may include an extraction plate 316. As illustrated in FIG. 7A, the extraction plate 316 partially separates the plasma chamber 310 from the process chamber 302. The extraction plate 316 also includes an aperture 324 providing gaseous communication between the plasma chamber 310 and the process chamber 302, where the aperture 324 acts as an extraction aperture. In this manner, the plasma chamber 310 may be coupled to the process chamber 302. The aperture 324 may be an elongated aperture that extends along a first direction, such as parallel to the X-axis, as shown in FIG. 7B. For example, the aperture 324 may have a width W ranging between 100 mm and 300 mm in some embodiments and a length L ranging between 3 mm and 30 mm in some embodiments. The embodiments are not limited in this context. This elongated configuration of aperture 324 allows the extraction of an ion beam ("plasma beam") as a ribbon beam, meaning an ion beam having a cross-section where the beam width is greater than a beam length.

As further shown in FIG. 7A, the apparatus 301 may include an inert gas source 312 coupled to the plasma chamber 310 to provide inert gas such as Ar, He, Ne, Kr, and so forth. The apparatus 301 may further include additional components such as a power generator 314, where the components together form a plasma source to generate a plasma 322.

The plasma 322 may be generated by coupling electric power from a power generator 314 to the rarefied gas provided by inert gas source 312 in the plasma chamber 310 through an adequate plasma exciter (not shown). As used herein, the generic term "plasma source" may include a power generator, plasma exciter, plasma chamber, and the plasma itself. The plasma source may be an inductively-coupled plasma (ICP) source, toroidal coupled plasma source (TCP), capacitively coupled plasma (CCP) source, helicon source, electron cyclotron resonance (ECR) source, indirectly heated cathode (IHC) source, glow discharge source, electron beam generated ion source, or other plasma sources known to those skilled in the art. Therefore, depending on the nature of the plasma source, the power generator 314 may be an rf generator, a dc power supply, or a microwave generator, while plasma exciter may include rf antenna, ferrite coupler, plates, heated/cold cathodes, helicon antenna, or microwave launchers. The apparatus 301 further may include a bias power supply 354 connected to the plasma chamber 310 or to a substrate stage 304, or to the plasma chamber 310 and substrate stage 304. Although not explicitly shown, the plasma chamber 310 may be electrically isolated from the process chamber 302. Extraction of a plasma beam 330 comprising positive ions through the aperture 324 may accomplished by either elevating the plasma chamber 310 at positive potential and grounding the substrate stage 304 directly or via grounding the process chamber 302, or by grounding the plasma chamber 310 and applying negative potential on the substrate stage 304. The bias power supply 354 may operate in either a DC mode or pulsed mode having a variable frequency and duty cycle, or an AC mode. The extraction plate 316 may be arranged generally according to known design to extract ions in the plasma beam 330 in a manner that allows control of the ion angular distribution, i.e., the angle of incidence of the plasma beam 330 with respect to a substrate 306 and the angular spread as detailed below.

In some embodiments, just one plasma beam 330 may be extracted through the aperture 324. In other embodiments, a pair of plasma beams may be extracted through the aperture 324. For example, as illustrated in FIG. 7A and FIG. 7B, a beam blocker 318 may be disposed within the plasma chamber 310 and adjacent the aperture 324, where the beam blocker 318 defines a first extraction aperture 360 and second extraction aperture 362. As shown in FIG. 7A, two plasma beams 330 may be extracted from the plasma chamber 310 and directed to the substrate 306.

As further shown in FIG. 7A, the apparatus 301 may include a pumping port 335 coupled to the plasma chamber 310 and a plasma chamber pump 334 connected to the pumping port 335. The plasma chamber pump 334 may be employed, for example, to reduce concentration of certain species within the plasma chamber 310, as discussed below. The apparatus 301 may further include a process chamber pump 336 coupled to the process chamber 302 via a pumping port 337 to evacuate the process chamber 302.

The apparatus 301 may further include a gas flow restrictor disposed between the reactive gas outlet and the extraction aperture, shown as the gas flow restrictor 320. As shown in FIG. 7A, for example, a gas flow restrictor 320 may be disposed on the outside of extraction plate 316 facing the substrate stage 304. The gas flow restrictor may define a differential pumping channel 340 between at least the plasma chamber 310 and substrate stage 304.

In operation, the substrate stage 304 may scan the substrate parallel to the Y-axis with respect to the extraction plate 316. In this manner, different portions of the substrate 306 may be exposed to the reactive gas 332 at different times. For example, the reactive gas outlet 309 may be elongated as shown in FIG. 7B and may have a width along the X-axis similar to the width W of the aperture 324, and a length along the Y-axis of 3 mm, for example. In various embodiments, the reactive gas outlet 309 may be composed of a multitude of small holes distributed over the X and Y dimensions to define an elongated shape as shown by the dashed lines, for uniform gas distribution along the X dimension. Moreover, the distance between the reactive gas source 308 and substrate 306 along the Z-axis may be 5 mm or less in some examples. The embodiments are not limited in this context. In this manner, the reactive gas 332 may be provided as a narrow, elongated stream that covers the substrate 306 in its entirety along the X-axis, while just covering the substrate 306 over several millimeters in the direction parallel to the Y-axis. Accordingly, the entirety of the substrate 306 may be exposed to the reactive gas 332 in a sequential fashion by scanning the substrate along the Y-axis. Likewise, different portions of the substrate 306 may be exposed to the plasma beam(s) 330 at different times.

Additionally, as illustrated in FIG. 7B, a given region, such as a region A of the substrate 306, may be exposed to the reactive gas 332 and plasma beam 330 in a sequential fashion. In this manner, in an example of scanning the substrate 306 from bottom to top, a product layer made from the species of the reactive gas 332 and substrate 306 may initially be formed at the region A. The product layer may be an ALE layer as discussed above where the product layer is a monolayer formed by a self-limiting reaction. The product layer formed in region A may be subsequently etched by the plasma beam 330, when the region A is scanned upwardly under the plasma beam 330. In this manner, the substrate 306 may be etched in a monolayer-by-monolayer fashion by sequentially scanning the substrate under the reactive gas 332 and plasma beam 330.

In accordance with embodiments of the disclosure, the gas flow restrictor 320 may define a low conductance channel, shown as differential pumping channel 340, between at least the extraction plate 316 and substrate stage 304. As discussed below, the differential pumping channel 340 may establish a large pressure difference between one end of the differential pumping channel 340 and the other end. The reactive gas source 308 is separated from the plasma chamber 310 by a large conductance aperture in direct communication to a pumping source. The pumping source can be the process chamber pump 336 or any other pumping source made to communicate with aperture 342. If the conductance of aperture 342 is represented by C142 and the conductance of differential pumping channel 340 by C140, the flow of the reactive gas exiting the reactive gas source 308 and flowing through aperture 342 is proportional to C142/(C142+C140), while the amount of gas exiting the reactive gas source 308 and flowing through differential pumping channel 340 is proportional to C140/(C142+C140). In accordance with various embodiments, using appropriate design of aperture 342 and differential pumping channel 340 the partial pressure of the reactive gas in these two spatial regions may differ by 2 to 3 orders of magnitude. Using this differential pumping method, the apparatus 301 may, for example, maintain a partial pressure of the reactive gas 332 adjacent the reactive gas outlet 309 of 1E-3 Torr, while having a partial pressure of 1E-6 Torr at the region 344 adjacent the aperture 324, leading to the plasma chamber 310.

A result of this pressure differential is that species of reactive gas 332 may be prevented from backstreaming into the region 344 or into plasma chamber 310, and may be preferentially pumped through the pumping port 337. This may facilitate the ability to control the composition of plasma beam 330, such as reducing or eliminating reactive gas species from the plasma beam 330. In this manner, a more controllable etch process may be realized by maintaining the exposure of substrate 306 to reactive gas 332 separate from the exposure to the plasma beam 330. Additionally, or alternatively, the plasma chamber 310 may be evacuated by the plasma chamber pump 334, further reducing the concentration of species from reactive gas 332 in plasma chamber 310.

In accordance with various embodiments, the substrate stage 304 may be scanned sequentially under the reactive gas source 308 and plasma chamber 310 while the reactive gas source 308 and plasma chamber 310 are maintained in an ON state. In this manner, the apparatus 301 may provide a high throughput ALE process. In particular, a purge cycle may be avoided where the reactive gas 332 would otherwise be purged between exposure to reactive gas and exposure to an etching process (e.g., plasma beam 330) as in known ALE processes. Moreover, in some embodiments, the substrate stage 304 may scan a substrate 306 back and forth (up and down in FIG. 7A) in a continuous fashion for a predetermined number of scan cycles in order to etch a predetermined amount of material from substrate 306. Since the thickness of a given product layer may be readily calculated, the total thickness to be etched may readily be controlled according to the number of scan cycles to be performed.

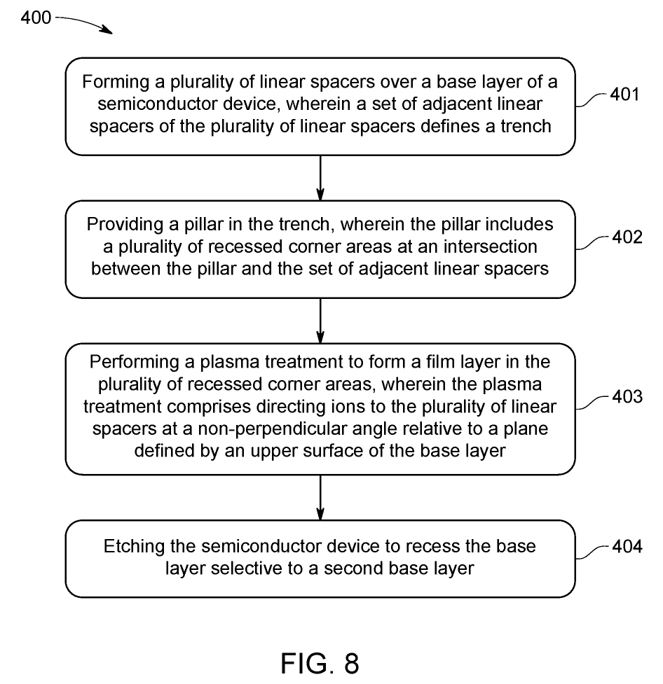

As shown in FIG. 8, the cluster processing system 200 and/or the apparatus 301 may be used to perform a process flow 400 to form the device 100 described herein. At block 401, process flow 400 may include forming a plurality of linear spacers over a base layer of a semiconductor device, wherein a set of adjacent linear spacers of the plurality of linear spacers define a trench.

In some embodiments, to form the plurality of linear spacers, a plurality of linear patterning features may first be provided atop the base layer, wherein each linear patterning feature includes an upper surface, and a set of sidewall surfaces connected to the upper surface. A spacer layer may then be formed over the plurality of linear patterning features, including over the upper surface and the set of sidewall surfaces. The spacer may then be removed from the upper surface of the plurality of linear patterning features, and the plurality of linear patterning features removed to form the plurality of linear spacers.

At block 402, the process flow 400 may further include providing a pillar in the trench, wherein the pillar includes a plurality of recessed corner areas at an intersection between the pillar and the set of adjacent linear spacers.

At block 403, the process flow 400 may further include performing a plasma treatment to form a film layer in the plurality of recessed corner areas, wherein the plasma treatment comprises directing ions to the plurality of linear spacers at a non-perpendicular angle relative to a plane defined by an upper surface of the base layer.

In some embodiments, forming the film layer may further include depositing the film layer over each of the following: the plurality of linear spacers, the pillar, and the base layer. In some embodiments, the plasma treatment may be a plasma etch, wherein the ions are directed to the plurality of linear spacers to remove the film layer from the plurality of linear spacers and from the base layer. In some embodiments, the film layer is removed from the plurality of linear spacers and from the base layer without being removed from the plurality of recessed corner areas. In some embodiments, performing the plasma treatment to form the film layer may include simultaneously depositing the film layer and etching the film layer. In some embodiments, performing the plasma treatment to form the film layer may include sequentially depositing the film layer and etching the film layer using a same processing tool. In some embodiments, performing the plasma treatment may further include directing ions to the plurality of linear spacers at an angle that is perpendicular to a plane defined by a sidewall of the plurality of linear spacers. In some embodiments, the film layer is further formed along a sidewall of the pillar.

At optional block 404, the process flow 400 may further include etching the semiconductor device to recess the base layer selective to a second base layer.

For the sake of convenience and clarity, terms such as "top," "bottom," "upper," "lower," "vertical," "horizontal," "lateral," and "longitudinal" will be understood as describing the relative placement and orientation of components and their constituent parts as appearing in the figures. The terminology will include the words specifically mentioned, derivatives thereof, and words of similar import.

Furthermore, the terms “substantial” or “substantially,” as well as the terms “approximate” or “approximately,” can be used interchangeably in some embodiments, and can be described using any relative measures acceptable by one of ordinary skill in the art. For example, these terms can serve as a comparison to a reference parameter, to indicate a deviation capable of providing the intended function. Although non-limiting, the deviation from the reference parameter can be, for example, in an amount of less than 1%, less than 3%, less than 5%, less than 10%, less than 15%, less than 20%, and so on.

Still furthermore, one of ordinary skill will understand when an element such as a layer, region, or substrate is referred to as being formed on, deposited on, or disposed “on,” “over” or “atop” another element, the element can be directly on the other element or intervening elements may also be present. In contrast, when an element is referred to as being “directly on,” “directly over” or “directly atop” another element, no intervening elements are present.

While certain embodiments of the disclosure have been described herein, the disclosure is not limited thereto, as the disclosure is as broad in scope as the art will allow and the specification may be read likewise. Therefore, the above description is not to be construed as limiting. Instead, the above description is merely as exemplifications of particular embodiments. Those skilled in the art will envision other modifications within the scope and spirit of the claims appended hereto.

What is claimed is:

1. A method, comprising:
forming a plurality of linear spacers over a base layer of a semiconductor device, wherein a set of adjacent linear spacers of the plurality of linear spacers define a trench;
providing a pillar in the trench, wherein the pillar comprises a plurality of recessed corner areas at an intersection between the pillar and the set of adjacent linear spacers; and
performing a plasma treatment to form a film layer in the plurality of recessed corner areas, wherein the plasma treatment comprises directing ions to the plurality of linear spacers at a non-perpendicular angle relative to a plane defined by an upper surface of the base layer.

2. The method of claim 1, wherein forming the film layer further comprises depositing the film layer over each of the following: the plurality of linear spacers, the pillar, and the base layer.

3. The method of claim 2, wherein the plasma treatment is a plasma etch, and wherein the ions are directed to the plurality of linear spacers to remove the film layer from the plurality of linear spacers and from the base layer.

4. The method of claim 3, wherein the film layer is removed from the plurality of linear spacers and from the base layer without being removed from the plurality of recessed corner areas.

5. The method of claim 1, wherein performing the plasma treatment to form the film layer comprises simultaneously depositing the film layer and etching the film layer.

6. The method of claim 1, wherein performing the plasma treatment to form the film layer comprises sequentially depositing the film layer and etching the film layer using a same processing tool.

7. The method of claim 1, wherein the plasma treatment further comprises directing ions to the plurality of linear spacers perpendicular to a plane defined by a sidewall of the plurality of linear spacers.

8. The method of claim 1, wherein the film layer is further formed along a sidewall of the pillar.

9. The method of claim 1, further comprising:
providing a plurality of linear patterning features atop the base layer, wherein each linear patterning feature includes an upper surface and a set of sidewall surfaces connected to the upper surface;
forming a spacer layer over the plurality of linear patterning features, including over the upper surface and the set of sidewall surfaces;
removing the spacer layer from the upper surface of the plurality of linear patterning features; and
removing the plurality of linear patterning features to form the plurality of linear spacers.

10. A self-aligned patterning method, comprising:
forming a plurality of linear spacers over a base layer of a semiconductor device, wherein a set of adjacent linear spacers of the plurality of linear spacers define a trench, wherein a pillar is formed in the trench, and wherein the pillar comprises a plurality of recessed corner areas at an intersection between the pillar and the set of adjacent linear spacers; and
performing a plasma treatment to form a film layer in the plurality of recessed corner areas and along a sidewall of the pillar, wherein the plasma treatment comprises directing ions to the plurality of linear spacers at a non-perpendicular angle relative to an upper surface of the base layer.

11. The self-aligned patterning method of claim 10, wherein forming the film layer further comprises depositing a carbon film layer over each of the following: the plurality of linear spacers, the pillar, and the base layer.

12. The self-aligned patterning method of claim 11, wherein the plasma treatment is a plasma etch, wherein oxygen or hydrogen ions are directed to the plurality of linear spacers to remove the carbon film layer from the plurality of linear spacers and from the base layer, and wherein the carbon film later is not removed from the plurality of recessed corner areas.

13. The self-aligned patterning method of claim 10, wherein performing the plasma treatment comprises simultaneously depositing the film layer and etching the film layer using a high-density plasma deposition process.

14. The self-aligned patterning method of claim 10, wherein the plasma treatment further comprises directing ions to the plurality of linear spacers perpendicular to a plane defined by a sidewall of the plurality of linear spacers.

15. The self-aligned patterning method of claim 10, further comprising etching the semiconductor device to recess the base layer selective to a second base layer.

16. The self-aligned patterning method of claim 10, further comprising:
providing a plurality of mandrel lines atop the base layer, wherein each mandrel line includes an upper surface and a set of sidewall surfaces connected to the upper surface;
forming a spacer layer over the plurality of mandrel lines, including over the upper surface and the set of sidewall surfaces;
removing the spacer layer from the upper surface of the plurality of mandrel lines; and
removing the mandrel lines to form the plurality of linear spacers.

17. A plasma processing tool, comprising:
a plasma chamber for generating plasma, wherein ions are extracted from the plasma and directed to a semiconductor device; and
a main controller operatively coupled to plasma chamber, wherein the main controller is adapted to perform a plasma treatment by directing the ions to a plurality of linear spacers of the semiconductor device to form a film layer in a plurality of recessed corner areas and along a sidewall of a pillar, wherein the pillar is formed between a set of adjacent linear spacers of the plurality of linear spacers, and wherein the ions are directed to the plurality of linear spacers at a non-perpendicular angle relative to an upper surface of a base layer of the semiconductor device.

18. The plasma processing tool of claim 17, wherein forming the film layer comprises depositing a carbon film layer over each of the following: the plurality of linear spacers, the pillar, and the base layer.

19. The plasma processing tool of claim 18, wherein the plasma treatment is a plasma etch, wherein oxygen or hydrogen ions are directed to the plurality of linear spacers to remove the carbon film layer from the plurality of linear spacers and from the base layer, and wherein the carbon film later is not removed from the plurality of recessed corner areas.

20. The plasma processing tool of claim 17, wherein performing the plasma treatment comprises simultaneously depositing the film layer and etching the film layer using a high-density plasma deposition process.
